(19) United States
(12) Patent Application Publication
(10) Pub. No.: US 2015/0168454 A1
(43) Pub. Date: Jun. 18, 2015

(54) PROBE MODULE

(71) Applicant: MPI CORPORATION, ZHUBEI (TW)

(72) Inventors: WEI-CHENG KU, ZHUBEI (TW); HAO WEI, ZHUBEI (TW); YOU-HAO CHEN, ZHUBEI (TW); CHIH-HAO HO, ZHUBEI (TW)

(73) Assignee: MPI CORPORATION, ZHUBEI (TW)

(21) Appl. No.: 14/557,786

(22) Filed: Dec. 2, 2014

(30) Foreign Application Priority Data
Dec. 13, 2013 (TW) 102146087

(51) Int. Cl. G01R 1/067; G01R 1/073; G01R 31/28; G01R 1/04

(52) U.S. Cl. CPC G01R 1/06794; G01R 1/0416; G01R 1/07314; G01R 31/2887

(57) ABSTRACT

A probe module, which is provided between a tester and a DUT for transmitting electrical signals therebetween, includes a PCB, a plurality of probes, a positioning member, and a signal connector. The PCB has a circuit and two grounding. The probes are electrical connected to the circuit and the groundings of the PCB. The positioning member is made of an insulating material, and provided on the probes. The positioning member is above the substrate, and the probes are between the substrate and the positioning member. The signal connector is adapted to be electrically connected to the tester, wherein the signal connector has a signal transmission portion and a grounding portion; the signal transmission portion is electrically connected to the circuit of the PCB, and the grounding portion is electrically connected to the at least one grounding of the PCB.

### BACKGROUND OF THE INVENTION

1. Technical Field

The present invention relates to an electrical testing device, and more particularly to a probe module.

2. Description of Related Art

Probe card is the commonest device to test the electrical connection of the electronic. The conventional probe card is electrically connected to a device under test (DUT) and a tester respectively to transmit electrical signals therebetween.

However, the probes might shift for a distance when they are in touch with the pads on the DUTs for several times. The shift of the probes makes an error in positioning the probes, and changes the characters of the electrical signals as well, which causes a false or incorrect detection.

Therefore, to avoid the shift of the probes is an important issue in the electrical test field.

### BRIEF SUMMARY OF THE INVENTION

In view of the above, the primary objective of the present invention is to provide a probe module, which has a high stability after times of operations.

In order to achieve the objective of the present invention, a probe module, which is provided between a tester and a DUT for transmitting electrical signals therebetween, includes a PCB, a plurality of probes, a positioning member, and a signal connector. The PCB has a circuit and at least one grounding. The probes are made of a conductive material, and electrical connected to the circuit and the at least one grounding of the PCB respectively. The probes are adapted to touch the DUT. The positioning member is made of an insulating material, and provided on the probes. The positioning member is above the substrate, and the probes are between the substrate and the positioning member. The signal connector is adapted to be electrically connected to the tester, wherein the signal connector has a signal transmission portion and a grounding portion; the signal transmission portion is electrically connected to the circuit of the PCB, and the grounding portion is electrically connected to the at least one grounding of the PCB.

With such design, the probes are firmly held by the positioning member to avoid the shifting problem.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of a preferred embodiment of the present invention;

FIG. 2 is an exploded view of the preferred embodiment of the present invention;

FIG. 3 is a perspective view of the preferred embodiment of the present invention, showing the probe set on the PCB;

FIG. 4 is a perspective view of the preferred embodiment of the present invention, showing the positioning member on the probe set;

FIG. 5 is a perspective view of the preferred embodiment of the present invention, showing the PCB on the bottom case; and

FIG. 6 is a perspective view of the preferred embodiment of the present invention, showing the top and the bottom cases and the PCB therebetween.

### DETAILED DESCRIPTION OF THE INVENTION

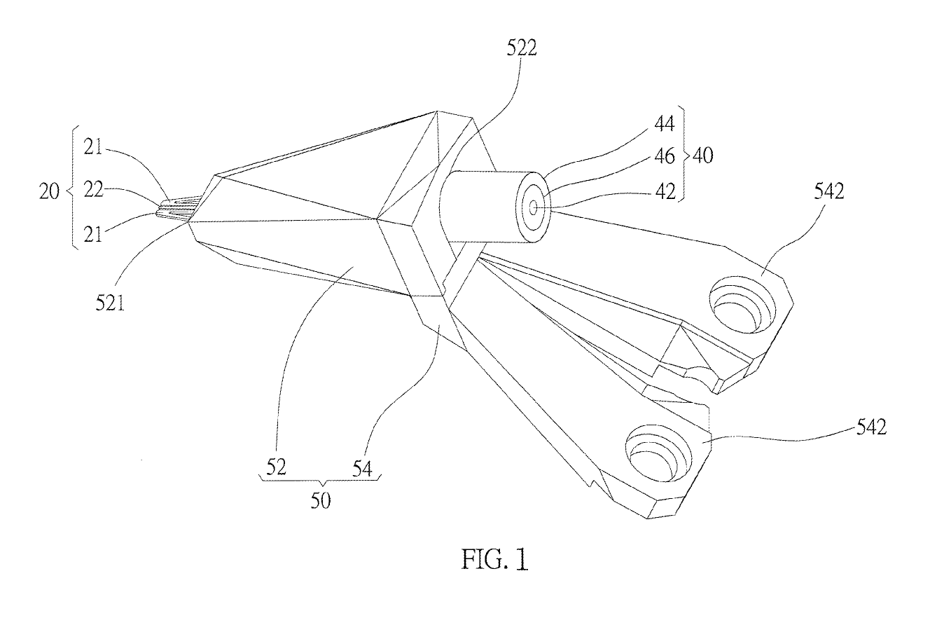

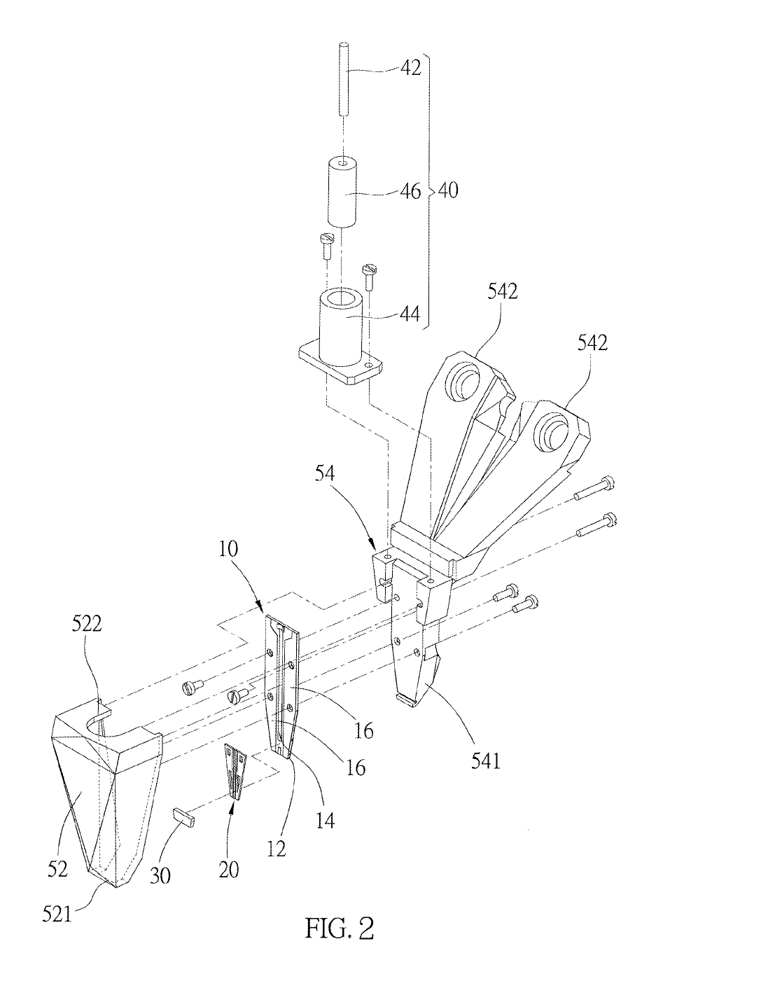

As shown in FIG. 1 and FIG. 2, a probe module of the preferred embodiment of the present invention, which is adapted to connect to a tester (not shown) and a DUT (not shown) respectively for transmitting electrical signals, includes a printed circuit board (PCB) 10, a probe set 20, a positioning member 30, a signal connector 40, and a housing 50.

The PCB 10, in the present embodiment, has a rectangular substrate 12, on which a circuit 14 and two groundings 16 are provided. The circuit 14 is between the groundings 16.

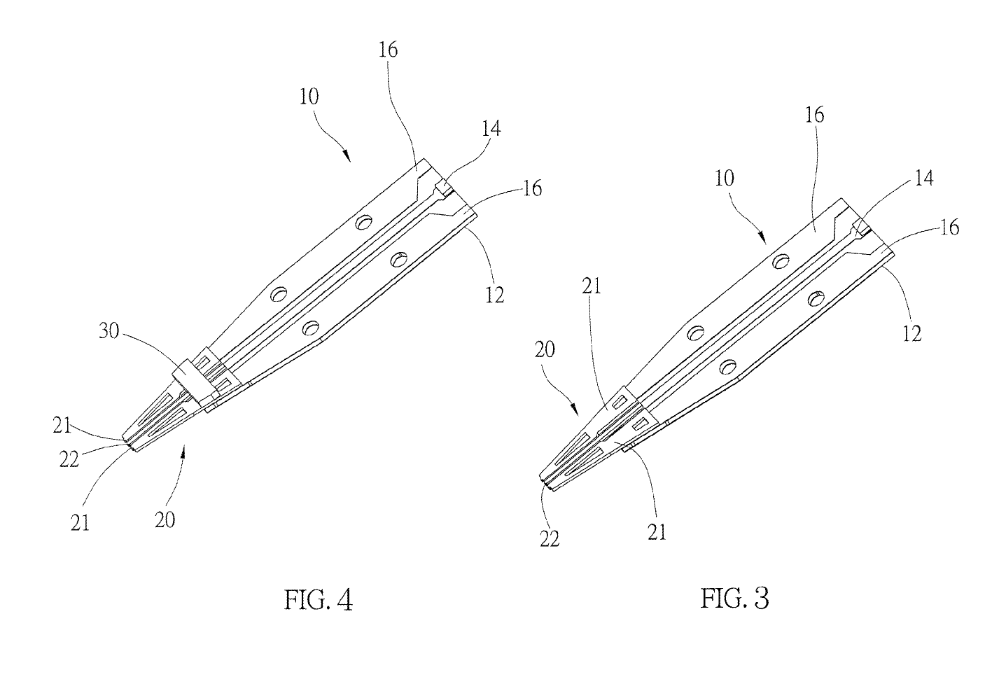

As shown in FIG. 3, the probe set 20 has three conductive probes, two of which are grounding probes 21, and the third of which is a signal probe 22. The probes are adapted to touch specific pads (not shown) on the DUT. A size of each grounding probe 21 is greater than that of the signal probe 22. Ends of the grounding probes 21 are fixed to the substrate 12 by welding, and electrically connected to the groundings 16 respectively. The signal probe 22 is fixed to the substrate 12 by welding as well, and electrically connected to the circuit 14. Therefore, the signal probe 22 is between the grounding probes 21.

As shown in FIG. 4, the positioning member 30 is made of epoxy and is attached to portions of top sides of the probes 21, 22 of the probe set 20, which are in the housing 50, by an insulating glue. The positioning member 30 crosses the probes 21, 22, and is in gaps between the probes 21, 22. When the probes 21, 22 are precisely adjusted to their positions, the positioning member 30 is provided to hold the probes 21, 22 of the probe set 20 firmly at their positions and insulate the probes 21, 22 from each other. In an embodiment, the positioning member 30 is made of other insulating material, and is attached to the probes 21, 22 only, which means that the positioning member 30 is not in the gaps between the probes 21, 22. It achieves the same holding function.

The signal connector 40 is connected to the PCB 10, and has a signal transmission portion 42 and a grounding portion 44. The signal transmission portion 42 is electrically connected to the circuit 14, and the grounding portion 44 is electrically connected to the grounding 16. In the present embodiment, the signal transmission portion 42 is a metal rod, and the grounding portion 44 is a metal ring surrounding the metal rod of the signal transmission portion 42. An insulating pad 46 is provided between the signal transmission portion 42 and the grounding portion 44 to avoid signal interference or short.

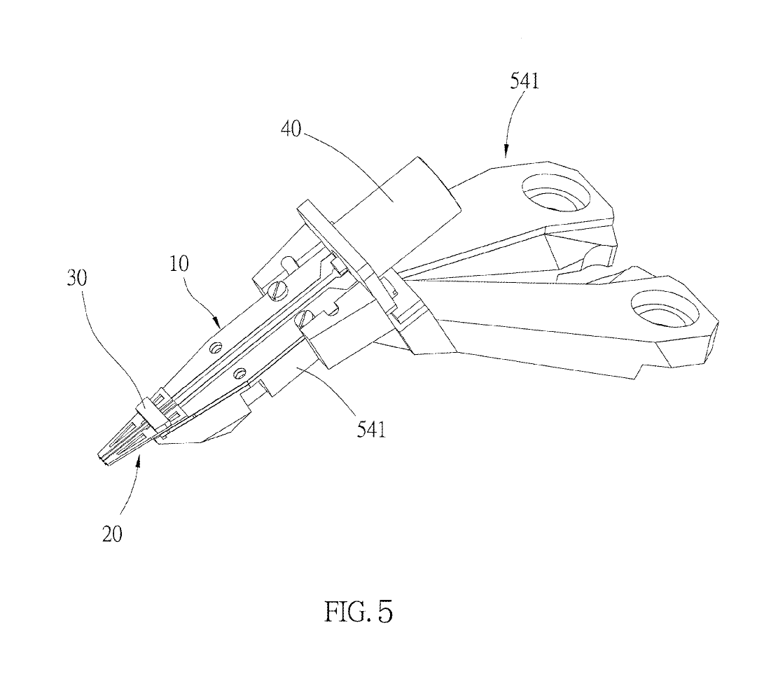

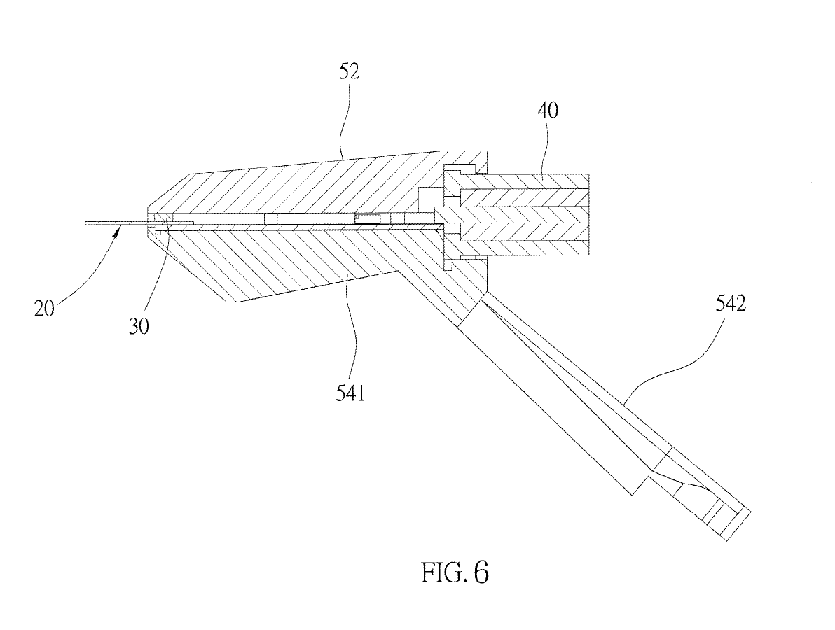

The housing 50 has a top case 52 and a bottom case 54 connected together to form a room therein. The top case 52 has a first opening 521 and a second opening 522 at opposite ends and communicated with the room. The bottom case 54 has a table 541 and two connecting boards 542 on a side of the table 541. As shown in FIG. 5, the PCB 10 and the signal connector 40 are secured on the table 541 of the bottom case 54 by bolts while the probe set 20, the positioning member 30, and the signal connector 40 are fixed to the PCB 10. Next, the top case 52 is connected to the table 541 to cover the PCB 10 on the table 541 thereunder and press the positioning member 30 to locate the positioning member 30 between the top case 52 and the PCB 10 (FIG. 6). The positioning member 30 gives a good electrical isolation between the top case 52 and the probe set 20. The probe set 20 extends out of the housing 50 via the first opening 521, and the signal connector 40 extends out of the housing 50 via the second opening 52.

In the beginning of a testing task, the operator secures the boards 542 to a testing arm of the tester, and connects the signal connector 40 to a coaxial cable of the tester. Next, the operator operates the tester to move the testing arm, so that the probe module is moved toward the DUT to make the probes 21, 22 of the probe set 20 touch specific pads of the DUT, and then it may start the testing task. With the positioning member 30, it may hold the probes 21, 22 of the probe set 20 firmly to avoid the shifting problem after plural times of testing tasks.

It must be pointed out that the embodiments described above are only some preferred embodiments of the present invention. All equivalent structures which employ the concepts disclosed in this specification and the appended claims should fall within the scope of the present invention.

What is claimed is:

1. A probe module, which is provided between a tester and a DUT for transmitting electrical signals therebetween, comprising:
a PCB having a substrate, on which a circuit and at least one grounding are provided;
a plurality of probes, which are made of a conductive material and adapted to touch the DUT, electrical connected to the circuit and the at least one grounding of the PCB respectively;
a positioning member, which is made of an insulating material, provided on the probes, wherein the positioning member is above the substrate, and the probes are between the substrate and the positioning member; and
a signal connector, which is adapted to be electrically connected to the tester, having a signal transmission portion and a grounding portion, wherein the signal transmission portion is electrically connected to the circuit of the PCB, and the grounding portion is electrically connected to the at least one grounding of the PCB.

2. The probe module of claim 1, further comprising a housing having a room therein and a first opening and a second opening at opposite ends of the housing and communicated with the room, wherein the PCB is received in the room; the probes extend out of the housing via the first opening, and the signal connector extends out of the housing via the second opening; the positioning member is provided on portions of the probes, which are out of the housing.

3. The probe module of claim 2, wherein the housing has a top case and a bottom case;
the PCB is connected to the bottom case; the bottom case has the first opening and the second opening, and the top case is connected to the bottom case to cover the PCB.

4. The probe module of claim 3, wherein the top case presses the positioning member to have the positioning member between the top case and the probes.

5. The probe module of claim 1, wherein the positioning member is received in a gap between the probes.

6. The probe module of claim 1, wherein the signal connector further includes an insulating pad between the signal transmission portion and the grounding portion.

7. The probe module of claim 1, wherein two of the at least one grounding are provided on the substrate, and electrically connected to the grounding portion of the signal connector; the circuit is between the groundings.

8. The probe module of claim 7, wherein three of the probes are provided, one of which is electrically connected to the circuit, and the other two of which are electrically connected to the groundings respectively.
